(19) United States
(12) Patent Application Publication
(10) Pub. No.: US 2026/0254325 A1
(43) Pub. Date: Aug. 27, 2026

(54) INTEGRATED RADIAL INVERTER

(71) Applicant: Schaeffler Technologies AG & Co. KG, Herzogenaurach (DE)

(72) Inventors: Philipp Wolters, Wooster, OH (US); David Burky, Massillon, OH (US); Avery Kaufmann, Wooster, OH (US); Andrew Wisniewski, South Lyon, MI (US); Salvatore Albanese, Chicago, IL (US)

(73) Assignee: Schaeffler Technologies AG & Co. KG, Herzogenaurach (DE)

(21) Appl. No.: 19/543,370

(22) Filed: Feb. 18, 2026

Related U.S. Application Data
(60) Provisional application No. 63/761,249, filed on Feb. 21, 2025.

(51) Int. Cl. H02K 11/33; H02M 1/44; H02M 7/00; H05K 7/14; H05K 7/20

(52) U.S. Cl. CPC H02K 11/33; H02M 1/44; H02M 7/003; H05K 7/14324; H05K 7/209; H05K 7/20927; H02K 2211/03

(57) ABSTRACT

An e-machine includes a housing, a rotationally fixed stator secured in the housing, a rotatable rotor arranged radially inside of the stator, and an inverter electrically connected to the stator and at least partially radially enclosed by the housing. The stator may have a plurality of first electrical connectors, and the inverter may have a plurality of second electrical connectors arranged to engage respective ones of the first electrical connectors to electrically connect the inverter to the stator.

### CROSS-REFERENCE TO RELATED APPLICATIONS

This application claims the benefit of U.S. Provisional Patent Application No. 63/761,249, filed Feb. 21, 2025, the disclosure of which is incorporated in its entirety by reference herein.

### TECHNICAL FIELD

The present disclosure relates generally to an inverter for an e-machine, and more specifically to an integrated radial inverter.

### BACKGROUND

Inverters for e-machines are known. One example is shown and described in United States Patent No. 12,075,601 titled HEAT DISSIPATION STRUCTURE FOR INVETER GRAOUND SCREWS OF A BELT STARTER GENERATOR, to Wang et al., hereby incorporated by reference as if set forth fully herein.

### SUMMARY

Example embodiments broadly comprise an e-machine including a housing, a rotationally fixed stator secured in the housing, a rotatable rotor arranged radially inside of the stator, and an inverter electrically connected to the stator and at least partially radially enclosed by the housing. In an example embodiment, the stator has a plurality of first electrical connectors, and the inverter has a plurality of second electrical connectors arranged to engage respective ones of the first electrical connectors to electrically connect the inverter to the stator.

In some example embodiments, the e-machine also includes a cooling plate. The inverter includes a printed circuit board (PCB), and the PCB is disposed axially between the cooling plate and the housing. In an example embodiment, the cooling plate includes a plurality of stacked plates. In some example embodiments, the cooling plate has an inlet for receiving a cooling fluid and an outlet for expelling the cooling fluid. In an example embodiment, the inlet and the outlet are hydraulically connected to respective hydraulic ports in the housing. In an example embodiment, the cooling plate also includes a cooling channel hydraulically connecting the inlet to the outlet. In some example embodiments, the inverter has a plurality of second electrical connectors, the cooling plate has a plurality of slots, and each of the plurality of second electrical connectors extends through a one of the plurality of slots. In an example embodiment, the inverter has a centrally located direct current (DC) link capacitor, and a plurality of power modules arranged radially outside of the DC link capacitor. Each of the plurality of second electrical connectors is arranged radially outside a one of the plurality of power modules.

In some example embodiments, the inverter includes a centrally located direct current (DC) link capacitor, and a plurality of power modules arranged radially outside of the DC link capacitor. In some example embodiments, the inverter also includes an electromagnetic interference (EMI) filter arranged radially outside of the DC link capacitor and rotationally offset from the plurality of power modules. In some example embodiments, the e-machine also includes a ring surrounding the power modules and the EMI filter. In an example embodiment, the ring has a socket, and the inverter has a low voltage connector installed in the socket. In some example embodiments, the e-machine also includes a cooling plate. The inverter has a plurality of legs arranged for pressing the plurality of power modules against the cooling plate. In an example embodiment, the cooling plate has a plurality of formed channels, each aligned with a one of the plurality of power modules.

In some example embodiments, the e-machine also includes a cover secured to the housing. The cover and the housing form at least a portion of a chamber, and the inverter is disposed in the chamber. In an example embodiment, the cover has an aperture, and the inverter has a low voltage connector extending through the aperture.

### BRIEF DESCRIPTION OF THE DRAWINGS

FIG. 1 illustrates a perspective view of an e-machine with a transparent housing and cover, according to an example embodiment.

FIG. 2 illustrates a cross-sectional, exploded, schematic view of the e-machine of FIG. 1.

FIG. 3 illustrates a perspective view of cross-sectional view of the e-machine of FIG. 1.

FIG. 4 illustrates a perspective view of an inverter and cooling plate of the e-machine of FIG. 1.

FIG. 5 illustrates an end view of the e-machine of FIG. 1 with a cover removed.

FIG. 6 illustrates a schematic, perspective, top view of the inverter and cooling plate of FIG. 4.

FIG. 7 illustrates a schematic, perspective, bottom view of the inverter and cooling plate of FIG. 4.

### DETAILED DESCRIPTION

Embodiments of the present disclosure are described herein. It should be appreciated that like drawing numbers appearing in different drawing views identify identical, or functionally similar, structural elements. Also, it is to be understood that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The terminology used herein is for the purpose of describing particular aspects only, and is not intended to limit the scope of the present disclosure. Unless defined otherwise, all technical and scientific terms used herein have the same meaning as commonly understood to one of ordinary skill in the art to which this disclosure belongs. Although any methods, devices or materials similar or equivalent to those described herein can be used in the practice or testing of the disclosure, the following example methods, devices, and materials are now described.

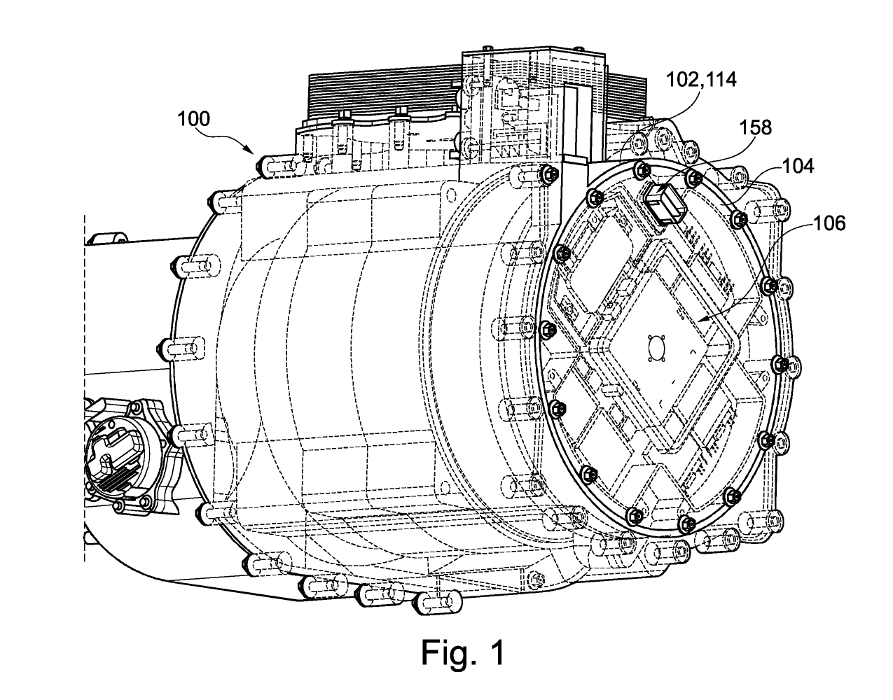

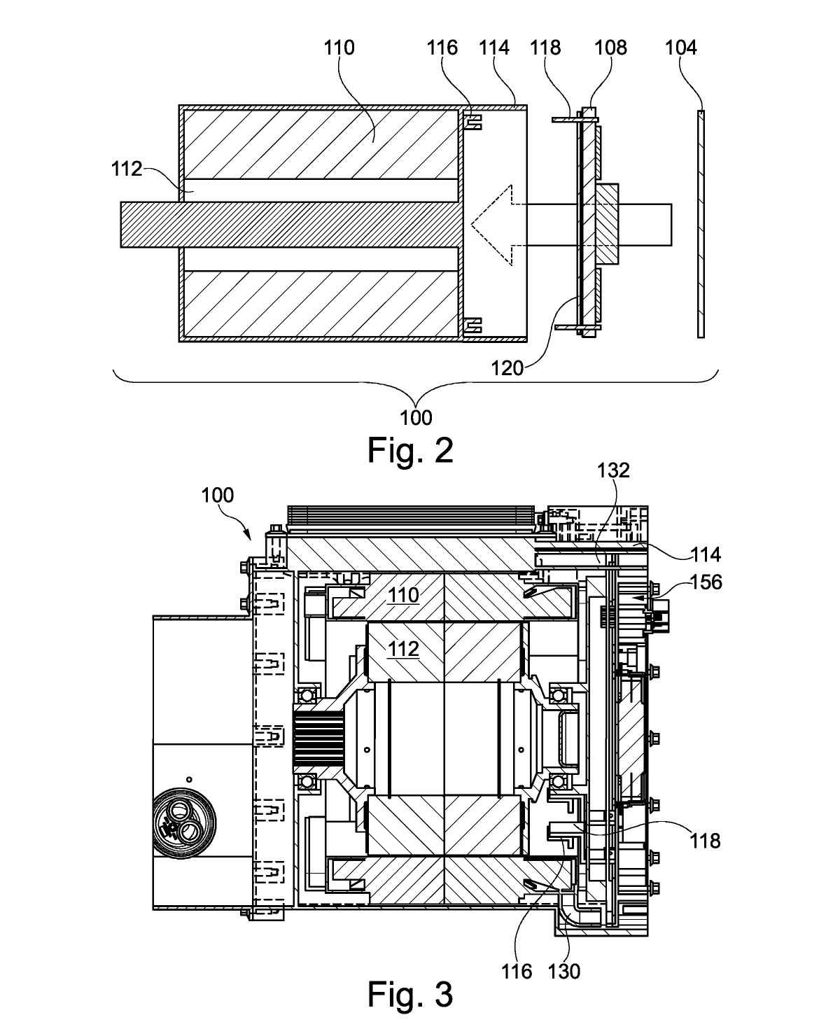

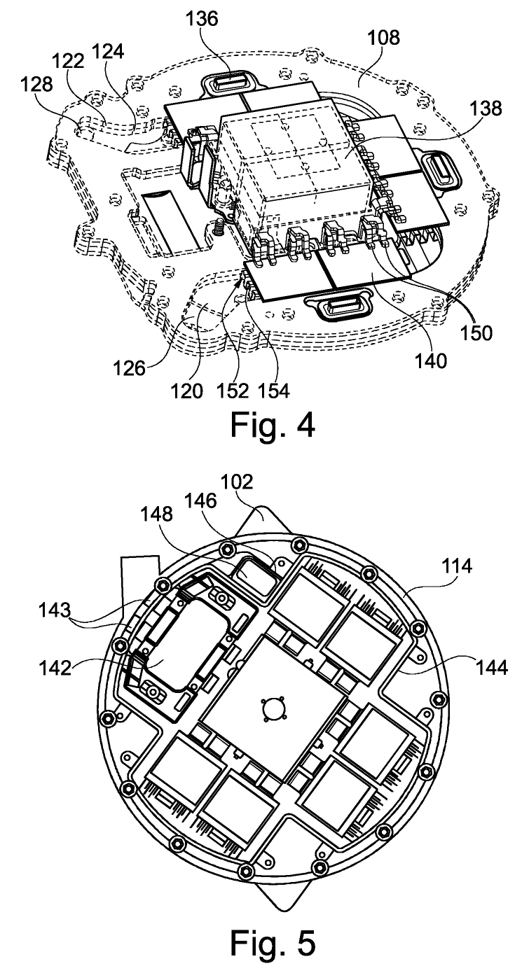

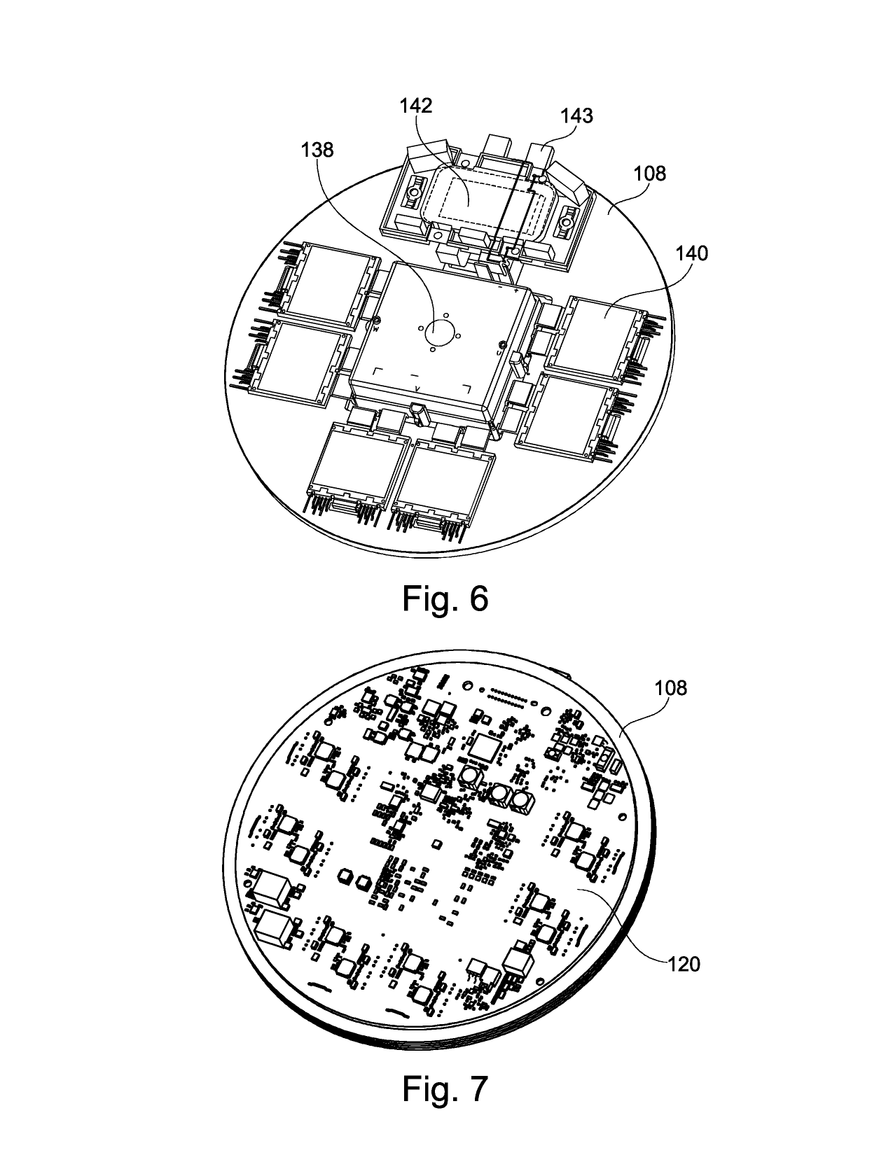

The following description is made with reference to FIGS. 1-7. FIG. 1 illustrates a perspective view of e-machine 100 with transparent housing 102 and cover 104. FIG. 2 illustrates a cross-sectional, exploded, schematic view of the e-machine of FIG. 1. FIG. 3 illustrates a perspective view of cross-sectional view of the e-machine of FIG. 1. FIG. 4 illustrates a perspective view of inverter 106 and cooling plate 108 of the e-machine of FIG. 1. FIG. 5 illustrates an end view of the e-machine of FIG. 1 with cover 104 removed. FIG. 6 illustrates a schematic, perspective, top view of the inverter and cooling plate of FIG. 4.

E-machine 100 includes housing 102, rotationally fixed stator 110 secured in the housing, rotatable rotor 112 arranged radially inside of the stator, and inverter 106 electrically connected to the stator and at least partially radially enclosed by the housing. By partially radially enclosed, we mean that the housing includes wall 114 arranged radially outside of the inverter such that at least a portion of the inverter is disposed radially within the wall. In the embodiments shown, wall 114 extends circumferentially around the inverter, for example. As shown best in FIGS. 2 and 3, for example, stator 110 includes electrical connectors 116 and inverter 106 includes electrical connectors 118 arranged to engage electrical connectors 116 to electrically connect the inverter to the stator. In the embodiment shown, electrical connectors 116 are depicted as female connectors and connectors 118 are depicted as male connectors, although other connector configurations are possible. Connectors 116 and 118 may be components of alternating current (AC) busbars, for example.

E-machine 100 also includes cooling plate 108. Inverter 106 includes printed circuit board (PCB) 120 and the PCB is disposed axially between the cooling plate and the housing. The PCB may include a control board and gate drivers, for example. As shown in FIG. 4, for example, cooling plate 108 may include stacked plates 122 and 124, for example. Cooling plate 108 includes inlet 126 for receiving a cooling fluid and outlet 128 for expelling the cooling fluid. As shown best in FIG. 3, for example, the inlet and the outlet are hydraulically connected to respective hydraulic ports 130 and 132 in the housing. Ports 130 and 132 are arranged to direct a cooling fluid through the cooling plate to cool the inverter, as described in more detail below. Cooling plate 108 also includes cooling channel 134 hydraulically connecting the inlet to the outlet. Cooling plate 108 also includes slots 136 and electrical connectors 118 extend through the slots.

As best shown in FIGS. 4-6, for example, inverter 106 includes centrally located direct current (DC) link capacitor 138, and power modules 140 arranged radially outside of the DC link capacitor. Electrical connectors 118 are arranged radially outside of power modules 140. Inverter 106 also includes electromagnetic interference (EMI) filter 142 arranged radially outside of the DC link capacitor and rotationally offset from the power modules. EMI filter 142 may include terminals 143 arranged to receive high voltage direct current (HV DC) from a battery, for example. E-machine 100 also includes ring 144 surrounding the power modules and the EMI filter. In the embodiment shown, ring 144 has somewhat of a clover shape. Ring 144 includes socket 146 and inverter 106 includes low voltage connector 148 installed in the socket.

As best shown in FIG. 4, for example, inverter 106 includes legs 150 arranged for pressing the power modules against the cooling plate. Legs 150 may be conductive and transmit electrical energy to the power modules, for example. Cooling plate 108 includes formed channels 152, each aligned with one of the power modules. Channels 152 may be formed by accordion-shaped metal plates 154 installed in cooling channels 134, for example. By making the metal plates accordion-shaped, a surface area of the plates in contact with the cooling fluid is increased, thereby better cooling the power modules. Legs 150 help assure that the power modules contact plates 154 for improved cooling.

E-machine 100 also includes cover 104 secured to the housing. Cover 104 and housing 102 form chamber 156, inverter 106 is disposed in the chamber. Cover 104 includes aperture 158 and low voltage connector 148 extends through the aperture.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

### REFERENCE NUMERALS

100 E-machine

102 Housing

104 Cover

106 Inverter

108 Cooling plate

110 Stator

112 Rotor

114 Wall (housing)

116 Electrical connectors (first, stator)

118 Electrical connectors (second, inverter)

120 Printed circuit board (PCB)

122 Plate (cooling plate)

124 Plate (cooling plate)

126 Inlet (cooling plate)

128 Outlet (cooling plate)

130 Hydraulic port (housing)

132 Hydraulic port (housing)

134 Cooling channel (cooling plate)

136 Slots (cooling plate)

138 DC link capacitor

140 Power modules

142 EMI filter

143 Terminals (HV DC)

144 Ring

146 Socket (ring)

148 Low voltage connector (inverter)

150 Legs (inverter)

152 Formed channels (cooling plate)

154 Metal plates (cooling plate)

156 Chamber

158 Aperture (cover)

What is claimed is:

1. An e-machine, comprising:
a housing;
a rotationally fixed stator secured in the housing;
a rotatable rotor arranged radially inside of the stator; and
an inverter electrically connected to the stator and at least partially radially enclosed by the housing.

2. The e-machine of claim 1, wherein:
the stator comprises a plurality of first electrical connectors; and
the inverter comprises a plurality of second electrical connectors arranged to engage respective ones of the first electrical connectors to electrically connect the inverter to the stator.

3. The e-machine of claim 1, further comprising a cooling plate, wherein the inverter comprises a printed circuit board (PCB) and the PCB is disposed axially between the cooling plate and the housing.

4. The e-machine of claim 3, wherein the cooling plate comprises a plurality of stacked plates.

5. The e-machine of claim 3, wherein the cooling plate comprises an inlet for receiving a cooling fluid and an outlet for expelling the cooling fluid.

6. The e-machine of claim 5, wherein the inlet and the outlet are hydraulically connected to respective hydraulic ports in the housing.

7. The e-machine of claim 5, wherein the cooling plate further comprises a cooling channel hydraulically connecting the inlet to the outlet.

8. The e-machine of claim 4, wherein:
the inverter comprises a plurality of second electrical connectors;
the cooling plate comprises a plurality of slots; and
each of the plurality of second electrical connectors extends through a one of the plurality of slots.

9. The e-machine of claim 8, wherein the inverter comprises:
a centrally located direct current (DC) link capacitor; and
a plurality of power modules arranged radially outside of the DC link capacitor, wherein each of the plurality of second electrical connectors is arranged radially outside a one of the plurality of power modules.

10. The e-machine of claim 1, wherein the inverter comprises:
a centrally located direct current (DC) link capacitor; and
a plurality of power modules arranged radially outside of the DC link capacitor.

11. The e-machine of claim 10, wherein the inverter further comprises an electromagnetic interference (EMI) filter arranged radially outside of the DC link capacitor and rotationally offset from the plurality of power modules.

12. The e-machine of claim 11, further comprising a ring surrounding the power modules and the EMI filter.

13. The e-machine of claim 12, wherein:
the ring comprises a socket; and
the inverter comprises a low voltage connector installed in the socket.

14. The e-machine of claim 10, further comprising a cooling plate, wherein the inverter further comprises a plurality of legs arranged for pressing the plurality of power modules against the cooling plate.

15. The e-machine of claim 14, wherein the cooling plate comprises a plurality of formed channels, each aligned with a one of the plurality of power modules.

16. The e-machine of claim 1, further comprising a cover secured to the housing, wherein:
the cover and the housing form at least a portion of a chamber; and
the inverter is disposed in the chamber.

17. The e-machine of claim 16, wherein:
the cover comprises an aperture; and
the inverter comprises a low voltage connector extending through the aperture.
